(19) United States
(12) Patent Application Publication
(10) Pub. No.: US 2013/0141108 A1
(43) Pub. Date: Jun. 6, 2013

(54) METHOD FOR RECOGNIZING A CRITICAL BATTERY CONDITION AFTER A RESET OF A BATTERY MONITORING DEVICE

(71) Applicants: Juergen Motz, Steinheim An Der Murr (DE); Joachim Kizler, Stuttgart (DE)

(72) Inventors: Juergen Motz, Steinheim An Der Murr (DE); Joachim Kizler, Stuttgart (DE)

(73) Assignee: ROBERT BOSCH GMBH, Stuttgart (DE)

(21) Appl. No.: 13/816,513

(22) PCT Filed: Jul. 14, 2011
(86) PCT No.: PCT/EP2011/062026

§ 371 Date: Feb. 12, 2013

(30) Foreign Application Priority Data
Aug. 26, 2010 (DE) 102010039785.7

(51) Int. Cl. G01R 31/36

(52) U.S. Cl. 324/426

(57) ABSTRACT

The invention relates to a method for recognising a critical battery condition after a reset (200) of a battery monitoring device (100), wherein a data item indicating the critical battery condition is stored (221) in a non-volatile memory (121) when a critical battery condition is recognised (220) by the battery monitoring device (100), and after the reset (200) of the battery monitoring device (100) a critical battery condition is recognised (211, 220) if the data item indicating the critical battery condition is stored in the non-volatile memory (121).

### BACKGROUND OF THE INVENTION

The present invention relates to a method for recognizing a critical battery state after resetting a battery monitoring device.

Devices and/or systems for monitoring starter batteries are being used ever more frequently in modern motor vehicles. An exemplary method for monitoring the starter battery is known from DE 101 06 508 A1.

U.S. Pat. No 5,698,965 A discloses a device for measuring a charge in a battery in which a switch-off signal can be stored in a non-volatile memory if a state of charge in a battery has fallen below a predetermined level. The memory is coupled to a switch for a consumer. If the signal is in the memory, the consumer is prevented from drawing energy from the battery.

A battery monitoring device is marketed by the applicant under the name “Electronic battery sensor (EBS)”. Said device is equipped with integrated evaluating electronics and senses different battery variables, such as voltage, current and temperature, from which a number of variables that describe the state of the starter battery are determined with the aid of software algorithms.

The energy efficiency management (EEM) system of modern vehicles uses this information in a purposeful manner, for example, in order to ensure that the battery charge is at least sufficiently maintained that the vehicle can be reliably started even after a longer period of time. If the information flows into the management system for the generator and engine, they can reduce the fuel consumption, consequently reducing the pollutant emissions and extending the battery serviceable life. The EEM system also uses this data to decide whether it is expedient and possible to temporarily switch off the engine within the scope of a start/stop operation. Essential factors in this case are the so-called predictors of the EBS that inform the EEM, whether, for example, the state of charge (State of Charge, SOC) of the battery is sufficient and whether the anticipated interruption in voltage would be acceptable at the next start-up (State of Function, SOF), so that overall the start-up capability of the vehicle is ensured.

If the battery monitoring device has been reset, for example, as a result of an initiated reset or as a result of a (short term) loss in sufficient battery voltage supply in the case of a discharged battery, said battery monitoring device must subsequently determine the state of the battery merely on the basis of the prevailing measured values alone. However, different polarization effects can have a great falsifying effect when determining said measured values, for example, if the battery has been heavily discharged prior to the reset procedure or when using an independent start-up device.

It is therefore desirable to provide an option for recognizing a critical battery state even after a reset of the battery monitoring device.

### SUMMARY OF THE INVENTION

In accordance with the invention, a method is proposed for recognizing a critical battery state after a reset of a battery monitoring device.

In accordance with the invention, a non-volatile memory is used to store a datum that characterizes a critical battery state. The data remain in the non-volatile memory even after a reset of the battery monitoring device and thus said data are available immediately after the reset procedure. Consequently, the invention provides the option for recognizing a critical battery state even after a reset of the battery monitoring device and even if at this point in time the result based merely on the measured values is false. After the reset procedure, the datum that characterizes a critical battery state is therefore used to validate the measuring results. If the datum is available in the memory, each EEM function that can cause the vehicle not to start is preferably deactivated; for example a start/stop operation, recuperation etc. Consequently, it is ensured that the vehicle does not fail to start. Once the battery monitoring device has recalibrated the internal battery model, all the functions can be activated according to the predetermined battery state. With respect to the options for recognizing a battery state, reference is made to the document DE 101 06 508 A1, mentioned in the introduction, and to the prior art mentioned therein.

A critical battery state is expediently recognized if the state of charge is below a first threshold value, for example 40%. A non-critical operating state is expediently recognized if the state of charge exceeds a second threshold value, for example 60%, wherein the second threshold value is greater than the first threshold value. As an alternative or in addition thereto, other characteristic variables of the battery state can also be used, for example, “State of Function” (SOF), “State of Health” (SOH) or the time trend of the current, voltage and temperature.

A critical battery state is expediently stored immediately or at least promptly within a few seconds. If at a subsequent point in time, a non-critical battery state is recognized, the datum can be deleted from the memory. The interval between recognizing the state and storing the datum should expediently not exceed a minute. The longer the interval, the higher the risk of the obtained information being lost, for example, as a result of a power failure.

Depending upon the non-volatile memory used, it is possible that only a limited number of write cycles are available. It is advantageous, particularly in this case, to store status data in particular only if a critical battery state prevails that could, for example, lead to a loss of start-up capability. It is also possible to postpone the deleting of the datum in order to save on the number of accesses being made. When a non-critical battery state is recognized, the datum does not particularly have to be deleted immediately, since this change in state is not critical. The option is available to delete the datum, for example, within the scope of an access that is already being made on the non-volatile memory, for which a regular access procedure is particularly available.

Even replacing the critical battery does not have a disadvantageous effect. Although the battery monitoring device does recognize a critical battery state—possibly incorrectly—using the stored datum after the reset procedure, the battery monitoring device calibrates itself independently after a specific period of time, so that the datum is then deleted. As an improvement, it is proposed that in the event of the battery being replaced, the stored datum is deleted, for example, by way of a new battery coding, expediently by the workshop performing the work. It is generally to be noted, that any critical battery state that has been recognized falsely is not critical for the operation of the vehicle, since only the functions that can cause the vehicle not to start are switched off In contrast, a critical battery state that is not recognized can lead to the vehicle failing to start and this is associated with particular discomfort for the driver.

Preferably, a non-volatile memory is used inside the battery monitoring device in order to keep the cabling and connection costs comparatively low. In a particularly advantageous manner, any existing memory can be used, so that it is also possible to implement the invention in any existing battery monitoring devices. For example, the EBS marketed by the applicant already comprises a NVM-unit (non-volatile memory unit) that is suitable for storing the datum. However, it goes without saying that a signal that indicates the critical battery state can also be processed outside the battery monitoring device, for example, for storing in another control device.

A battery monitoring device in accordance with the invention comprises a data processing unit that comprises the programming technology to be able to perform the method in accordance with the invention.

It is also advantageous to implement the method in the form of software, since this results in particularly comparatively low costs especially if a control device that performs the method is also used for other tasks and therefore is already available. Suitable data carriers for providing the computer program are inter alia, in particular, diskettes, hard drives, flash memories, EEPROMs, CD-ROMs and DVDs. It is also possible to download a program via computer networks (Internet, Intranet etc.).

Further advantages and embodiments of the invention are evident from the description and the attached drawing.

It goes without saying that the aforementioned features and the features yet to be mentioned hereinunder can be used not only in the respective combination mentioned but also in other combinations or standing alone without abandoning the scope of the present invention.

The invention is illustrated schematically with the aid of an exemplary embodiment in the drawing and is described in detail hereinunder with reference to the drawing.

### BRIEF DESCRIPTION OF THE DRAWINGS

FIG. 1 shows a preferred embodiment of a battery monitoring device in accordance with the invention in an energy supply system of a motor vehicle.

FIG. 2 shows a preferred embodiment of a method in accordance with the invention as a state machine with reference to an illustration.

### DETAILED DESCRIPTION

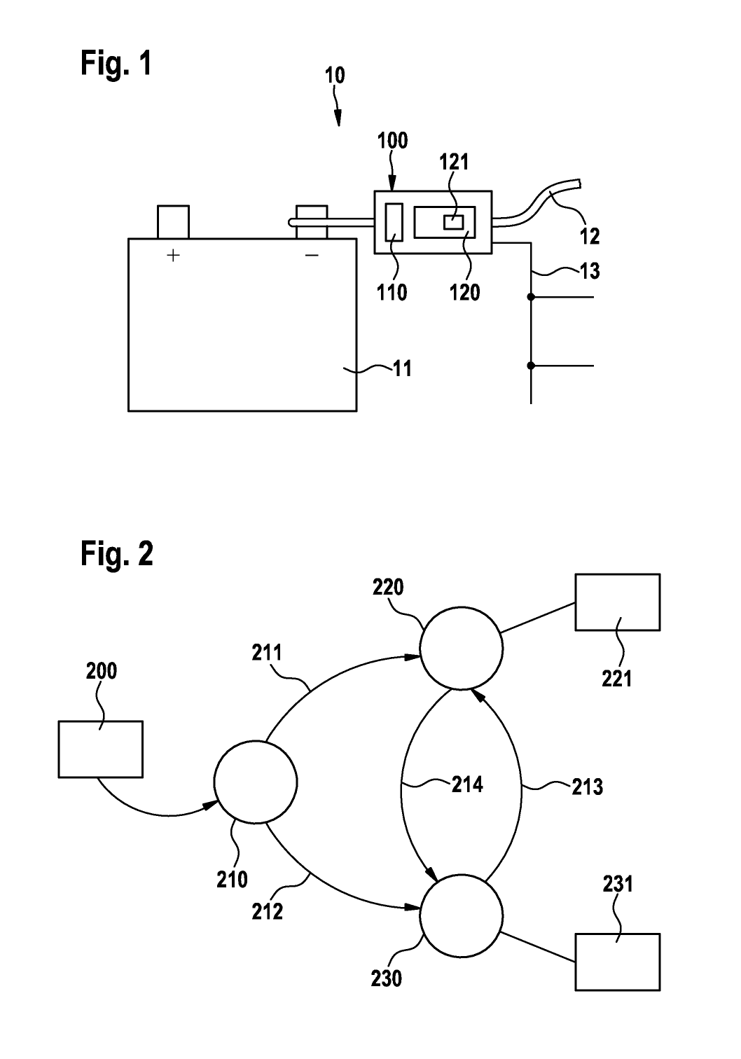

FIG. 1 shows a schematic illustration of a preferred embodiment 100 of a battery monitoring device in accordance with the invention in an energy supply system 10 of a motor vehicle. The battery monitoring device 100 is connected between a negative pole of a starter battery 11 and a battery cable 12 of the motor vehicle.

The battery monitoring device 100 comprises a measuring part 110 that measures a series of variables of the battery 11. In addition, the battery monitoring device 100 comprises a data processing unit 120 for evaluating the measured variables and for determining the battery state. The data processing unit 120 comprises a non-volatile memory 121 for storing inter alia a datum that characterizes a critical battery state. The battery monitoring device 100 is connected via a connection 13, in particular a bus connection, to further components of the vehicle, in particular control devices.

FIG. 2 illustrates a preferred embodiment of the invention in the form of a state machine. The invention is described with reference to the battery monitoring device 100 in accordance with FIG. 1.

Following a reset 200 of the battery monitoring device 100 which can be brought about, for example, as a result of loss of supply voltage, the battery monitoring device 100 (referred to hereinunder as the system) initially assumes an initialization state 210, in which it checks whether a datum that characterizes a critical state is stored in the non-volatile memory 121. If this is the case, the system moves along the connection 211 into a state 220 that is defined by the recognition of a critical battery state.

If, on the other hand, it is established in state 210 that the datum that characterizes the critical battery state is not stored in the memory 121, the system moves along a connection 212 into the state 230 that is characterized by the recognition of a non-critical battery state.

If the system is in the state 220, the datum in accordance with 221 that characterizes the critical battery state is stored immediately, i.e. preferably within one second or a few seconds, in the non-volatile memory 121. In addition, EEM-functions that are relevant for the start-up capability are deactivated.

If the system is in the state 230, a datum in accordance with 231 that is possibly available in the non-volatile memory 121 is deleted within the scope of a memory access that already takes place, for example, within the scope of a regular storage cycle. In addition, EEM-functions that are relevant for the start-up capability are activated.

The system moves between the states 220 and 230 along the connections 213 and 214. If the system is in the state 230 and a critical battery state is established, because, for example, the state of battery charge is below a first threshold value of 40%, then the system moves along 213 into the state 220.

If the system is in the state 220 and a non-critical battery state is established, because for example, the state of battery charge exceeds a second threshold value of 60%, the system moves along 214 into the state 230. It is also possible, for example, when re-calibrating the sensor to recognize that a threshold value has been exceeded.

Consequently, it is possible within the scope of the invention to provide a simple and reliable solution for recognizing a critical battery state even after a reset of the battery monitoring device.

1. A method for recognizing a critical battery state after resetting a battery monitoring device (100), wherein a datum that indicates the critical battery state is stored (221) in a non-volatile memory (121) if the battery monitoring device (100) recognizes (220) a critical battery state, and a critical battery state is recognized (211, 220) after resetting (200) the battery monitoring device if the datum that indicates the critical battery state is stored in the non-volatile memory (121), wherein the datum that indicates the critical battery state is deleted (231) from the non-volatile memory (121) if a non-critical battery state is recognized (230).

2. The method as claimed in claim 1, wherein a critical battery state is recognized (220) if a value that characterizes the battery state is below a first threshold value.

3. (canceled)

4. (canceled)

5. The method as claimed in claim 1, wherein a non-critical battery state is recognized (230) if a value that characterizes the battery state exceeds a second threshold value.

6. The method as claimed in claim 1, wherein functions that could cause the vehicle to fail to start are deactivated (221) if a critical battery state is recognized (220).

7. The method as claimed in claim 6, wherein functions that could cause the vehicle to fail to start are deactivated (221) if a critical battery state is recognized (211, 220) after resetting (200) the battery monitoring device.

8. The method as claimed in claim 1, wherein the datum that indicates the critical battery state is stored (221) in the non-volatile memory (121) immediately or promptly if the battery monitoring device (100) recognizes (220) a critical battery state.

9. A battery monitoring device (100) having a data processing unit (120) that is equipped for the purpose of performing a method as claimed in claim 1, and having an integrated non-volatile memory (121) for storing the datum that indicates the critical battery state.

10. (canceled)

11. The method as claimed in claim 2, wherein the battery state is a state of charge.

12. The method as claimed in claim 5, wherein the battery state is a state of charge.

13. The method as claimed in claim 1, wherein the datum that indicates the critical battery state is stored (221) in the non-volatile memory (121) within one second if the battery monitoring device (100) recognizes (220) a critical battery state.

14. The method as claimed in claim 1, wherein the datum that indicates the critical battery state is stored (221) in the non-volatile memory (121) within ten seconds if the battery monitoring device (100) recognizes (220) a critical battery state.

15. The method as claimed in claim 1, wherein the datum that indicates the critical battery state is stored (221) in the non-volatile memory (121) within sixty seconds if the battery monitoring device (100) recognizes (220) a critical battery state.
